(19) United States
(12) Patent Application Publication
(10) Pub. No.: US 2015/0093867 A1
(43) Pub. Date: Apr. 2, 2015

(54) METHOD OF FABRICATING SEMICONDUCTOR DEVICE

(71) Applicant: Samsung Electronics Co., Ltd., Suwon-si (KR)

(72) Inventor: Dong-Kyu LEE, Suwon-si (KR)

(73) Assignee: Samsung Electronics Co., Ltd., Suwon-si (KR)

(21) Appl. No.: 14/291,047

(22) Filed: May 30, 2014

(30) Foreign Application Priority Data
Sep. 27, 2013 (KR) 10-2013-0115403

(51) Int. Cl. H01L 21/8234

(52) U.S. Cl. CPC H01L 21/823462
USPC 438/275

(57) ABSTRACT

A method for fabricating a semiconductor device includes preparing a substrate in which a first active region and a second active region are defined by a device isolation region, forming a channel region in the first active region and the second active region, respectively, forming a gate insulating layer on the first active region and a gate insulating layer on the second active region, a thickness of the gate insulating layer on the first active region being different from a thickness of the gate insulating layer on the second active region, and forming a first interface layer between the substrate and the gate insulating layer on the first active region and a second interface layer between the substrate and the gate insulating layer on the second active region.

### CROSS-REFERENCE TO RELATED APPLICATION

This application claims priority from Korean Patent Application No. 10-2013-0115403 filed on Sep. 27, 2013 in the Korean Intellectual Property Office, and all the benefits accruing therefrom under 35 U.S.C. 119, the contents of which in its entirety are herein incorporated by reference.

### TECHNICAL FIELD

The present disclosure relates to a method for fabricating a semiconductor device.

### BACKGROUND

A speed of a metal-oxide semiconductor (MOS) transistor is closely related to a driving current of the MOS transistor and the driving current is closely related to mobility of charges. For example, when electron mobility in a channel region is high, an NMOS transistor has a high driving current. In contrast, when hole mobility in the channel regions is high, a PMOS transistor has a high driving current.

A complex semiconductor material (generally, known as a III-V group complex semiconductor), which is formed of III group and V group elements, has high electron mobility so as to be used to form an NMOS transistor. Accordingly, the III-V group complex semiconductor has been used to form an NMOS transistor. In order to reduce manufacturing cost, methods for forming a PMOS transistor using a III-V group complex semiconductor have also been studied.

### SUMMARY

The present embodiments have been made in an effort to provide a method for fabricating a semiconductor device which includes an interface layer, in order to improve an interface characteristic between a channel and a gate insulating layer while including a high mobility channel.

Technical problems of the present disclosure are not limited to the above-mentioned technical problems, and other technical problems, which are not mentioned above, can be clearly understood by those skilled in the art from the following descriptions.

In one embodiment, a method of fabricating a semiconductor device includes: preparing a substrate in which a first active region and a second active region are defined by a device isolation region; forming a channel region in the first active region and the second active region, respectively; forming a first gate insulating layer on the substrate at the first active region; and forming a second gate insulating layer on the first gate insulating layer at the first active region and on the substrate at the second active region. The first gate insulating layer is disposed between the substrate and the second gate insulating layer at the first active region, and is not disposed between the substrate and the second gate insulating layer at the second active region. The method further includes, after forming the first gate insulating layer and second gate insulating layer, forming a first interface layer at an interface between the substrate and the first gate insulating layer at the first active region, and forming a second interface layer at the interface between the substrate and the second gate insulating layer at the second active region.

In another embodiment, a method for fabricating a semiconductor device includes: preparing a substrate in which a first active region and a second active region are defined by a device isolation region; forming a channel region in the first active region and the second active region, respectively; forming a gate insulating layer, referred to as gate insulating layer 1, on the first active region and a gate insulating layer, referred to as gate insulating layer 2, on the second active region, a thickness of the gate insulating layer 1 being greater than a thickness of the gate insulating layer 2; and forming a first interface layer between the substrate and the gate insulating layer 1 and a second interface layer between the substrate and the gate insulating layer 2.

In a further embodiment, a method of fabricating a semiconductor device includes: preparing a substrate in which a first active region and a second active region are defined by a device isolation region; forming a channel region in the first active region and the second active region, respectively; forming a first gate insulating layer on the substrate at the first active region; forming a second gate insulating layer on the first gate insulating layer at the first active region and on the substrate at the second active region, such that the first gate insulating layer and second gate insulating layer at the first active region form a gate insulating layer 1 having exposed top and side surfaces, and the second insulating layer at the second region forms a gate insulating layer 2 having exposed top and side surfaces; and after forming the gate insulating layer 1 and the gate insulating layer 2, forming a first interface layer at an interface between the substrate and the gate insulating layer 1 at the first active region, and forming a second interface layer at the interface between the substrate and the gate insulating layer 2 at the second active region.

### BRIEF DESCRIPTION OF THE DRAWINGS

The above and other features and advantages of the present disclosure will become more apparent by describing in detail embodiments thereof with reference to the attached drawings in which:

FIG. 1 is a cross-sectional view of an exemplary semiconductor device according to one embodiment;

FIGS. 2 to 8 are diagrams illustrating exemplary intermediate processes of a method for fabricating a semiconductor device according to certain embodiments;

FIGS. 9 to 11 are diagrams illustrating exemplary intermediate processes of a method for fabricating a semiconductor device according to other embodiments;

FIGS. 12 to 17 are diagrams illustrating exemplary intermediate processes of a method for fabricating a semiconductor device according to yet another embodiment;

FIGS. 18 and 19 are diagrams illustrating exemplary intermediate processes of a method for fabricating a semiconductor device according to still another embodiment;

FIG. 20 is a block diagram illustrating an exemplary electronic system which includes a semiconductor device according to some embodiments; and

FIGS. 21 and 22 illustrate an exemplary semiconductor system to which a semiconductor device according to some embodiments may be applied.

### DETAILED DESCRIPTION

Advantages and features of the disclosed embodiments and methods of accomplishing the same may be understood more readily by reference to the following detailed description and the accompanying drawings. The present inventive concept may, however, be embodied in many different forms and should not be construed as being limited to the embodiments set forth herein. Like reference numerals refer to like elements throughout the specification.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. Terms such as “between” and “adjacent” should be treated similarly. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to limit the scope of the present inventive concept.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

According to a semiconductor device and a fabricating method thereof which will be described below, in a semiconductor device which is formed of a channel having high mobility, a thickness of a gate insulating layer of a first active region is different from a thickness of a gate insulating layer of a second active region. To this end, a semiconductor material having a high mobility characteristic may be included in a channel of the first active region and a channel of the second active region and an interface layer may be formed in order to improve an interface characteristic between the channels and the gate insulating layers. Some embodiments disclose a method for forming such an interface layer. In a semiconductor device, a thickness of the gate insulating layer may vary depending on a usage purpose of the semiconductor device.

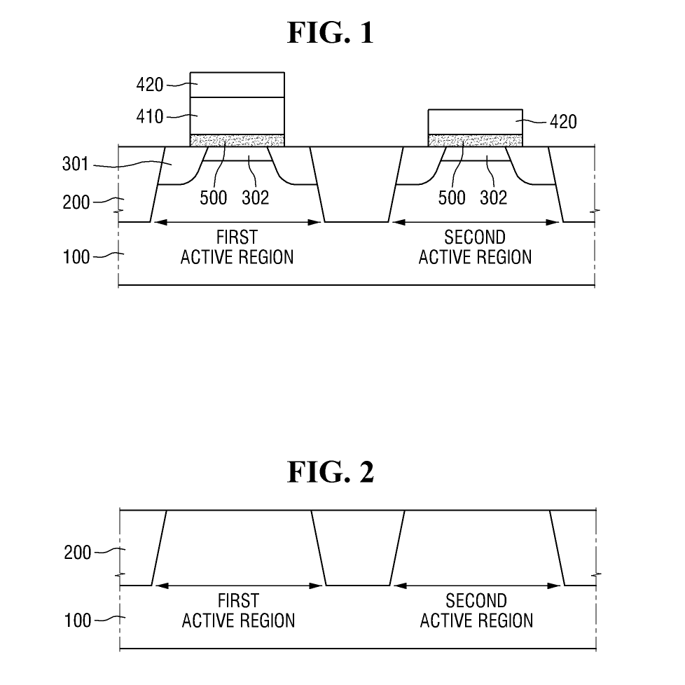

FIG. 1 is a cross-sectional view of a semiconductor device according to one exemplary embodiment.

Referring to FIG. 1, a semiconductor device according to one embodiment includes a substrate 100, a device isolation region 200, a source/drain 301, a channel region 302, an interface layer 500, a first gate insulating layer 410, and a second gate insulating layer 420.

The substrate 100 may be a rigid substrate such as, for example, a silicon substrate, a silicon on insulator (SOI) substrate, a gallium arsenic substrate, a silicon germanium substrate, a ceramic substrate, a quartz substrate, or a display glass substrate.

The device isolation region 200 is formed in the substrate 100 to define an active region. Referring to FIG. 1, a first active region and a second active region are defined in the substrate 100 by the device isolation region 200. For example, in one embodiment, the first active region may be a region which includes a high voltage device and the second active region may be a region which includes a low voltage device. However, the active regions are not limited thereto. As illustrated in FIG. 1, the device isolation region 200 may be a shallow trench isolation (STI), but is not limited thereto.

The source/drain 301 is disposed on both sides of a gate pattern in the substrate 100. The source/drain 301 may have any shape. For example, the source/drain 301 may be a lightly doped drain (LDD). Unlike FIG. 1, the source/drain 301 may be an elevated source/drain. In this case, a top surface of the source/drain 301 may be higher than a top surface of the substrate 100. Further, the source/drain 301 may be formed by forming a recess at both sides of the gate pattern and using an epitaxial process. Further, such a source/drain 301 may include Ge, GeSn, or a III-V group compound.

The channel region 302 is formed in the substrate 100. Referring to FIG. 1, the channel region 302 is formed in the first active region and the second active region, respectively. Each channel region 302 is formed between a first source/drain 301 and a second source/drain 301. The channel region 302 may be formed, for example, by an epitaxial growth method. The channel region 302 may be formed, in one example, by a wafer bonding method or formed by epitaxial growing a strained channel on a strain relaxed buffer (SRB). In one embodiment, the channel region 302 is formed of a material which may improve carrier mobility. For example, the channel region 302 may include germanium (Ge) or a III-V group semiconductor compound. The channel region 302 may be a single layer or a multi-layer.

The interface layer 500 is formed on the first active region and the second active region. Specifically, the interface layer 500 may be formed on regions of the first active region and the second active region in which the channel region 302 is formed. The interface layer 500 may serve to prevent a faulty interface between the channel region 302 and the first gate insulating layer 410 or between the channel region 302 and the second gate insulating layer 420. When the channel region 302 is formed to include germanium (Ge) or the III-V group semiconductor compound, the interface layer 500 may be desirable to be formed between the channel region 302 and the first gate insulating layer 410 or between the channel region 302 and the second gate insulating layer 420. For example, when the first gate insulating layer 410 or the second gate insulating layer 420 includes a high-K material, the interface layer 500 improves an interface characteristic between the channel region 302 and the first gate insulating layer 410 or between the channel region 302 and the second gate insulating layer 420.

The first gate insulating layer 410 is formed on the interface layer 500 which is formed on the first active region. The first gate insulating layer 410 may include, for example, a material having a high dielectric constant (high-K). Specifically, the first gate insulating layer 410 may include one or more of materials selected from a group consisting of, for example, Al₂O₃, ZnO, HfSiON, HfO, ZrO₂, Ta₂O₅, TiO₂, SrTiO₃, BaTiO₃, and SrTiO₃. The first gate insulating layer 410 may be formed to have an appropriate thickness depending on a type of a device to be formed. For example, when the first gate insulating layer 410 is HfO, the first gate insulating layer 410 may be formed to have a thickness of approximately 50 Å or less (e.g., approximately, 5 Å to 50 Å), but is not limited thereto.

Generally, the thickness of the gate insulating layer is an important parameter for determining a threshold voltage of a semiconductor device. Therefore, as the thickness of the gate insulating layer is changed, the threshold voltage is also changed. For example, a thickness of a gate insulating layer for a low voltage input/output (I/O) device which demands a high-performance may be relatively thin, e.g., 10 Å to 20 Å but a thickness of a gate insulating layer for a high voltage core logic device may be relatively thick, e.g., 20 Å to 100 Å. In certain embodiments, the thickness of the gate insulating layer for a high voltage device may be between about 2 and 5 times the thickness of the gate insulating layer for a low voltage device. As an operation speed of electronic apparatuses increases, a variety of thicknesses of gate insulating layers of a MOSFET device may be used.

The second gate insulating layer 420 is formed on the interface layer 500 which is formed on the second active region. The second gate insulating layer 420 may include a material having a high dielectric constant (high-K). Specifically, the second gate insulating layer 420 may include one or more of materials selected from a group consisting of, for example, Al₂O₃, ZnO, HfSiON, HfO, ZrO₂, Ta₂O₅, TiO₂, SrTiO₃, BaTiO₃, and SrTiO₃. The second gate insulating layer 420 may be formed to have an appropriate thickness depending on a type of a device to be formed. The first gate insulating layer 410 and second gate insulating layer 420 may be formed of the same material or of different materials. In certain embodiments, the thickness of the second gate insulating layer 420 is different from the thickness of the first gate insulating layer 410.

Though the interface layer 500 is shown in FIG. 1 to be disposed above the channel regions 302 and source/drain regions 301, in certain embodiments the interface layer 500 extends into the channel regions 302 and source/drain regions 301 such that part of the interface layer is below what is shown as the top surface of channel regions 302 and source/drain regions 301 in FIG. 1 (e.g., a top surface of the substrate 100), and part of the interface layer is disposed above that top surface. In one embodiment, the interface layer includes a material having a low dielectric constant (low-K), such as GeOx, compared to the high-K material included in the first gate insulation layer 410 and second gate insulating layer 420.

The interface layer 500 may be a relatively thin layer, for example, compared to the first gate insulation layer 410 and second gate insulating layer 420. For example, in one embodiment, the interface layer may have a thickness of about 5 Å to 100 Å. In certain embodiments, the interface layer may have between about 10% and 50% of the thickness of either the first gate insulating layer 410 or the second gate insulating layer 420. Further, if a different material is used for the different channel regions 302, a thickness of the interface layer can be different for the different channel regions 302. In addition, due to a Plasma Post Oxidation procedure, which as described below may be used to form the interface layer 500, the introduction of the interface layer 500 may increase the overall thickness of the gate insulating layer (e.g., the combined first gate insulating layer 410, second gate insulating layer 420, and interface layer 500) above the top surface of the substrate 100. For ease of description, an insulating layer at the first active region (e.g., including one or more sub-layers such as 410, 420, and/or 500) may be generally referred to herein as insulating layer 1, and an insulating layer at the second active region (e.g., including one or more sub-layers) may be generally referred to herein as insulating layer 2.

Hereinafter, an exemplary method for fabricating a semiconductor device according to certain embodiments will be described.

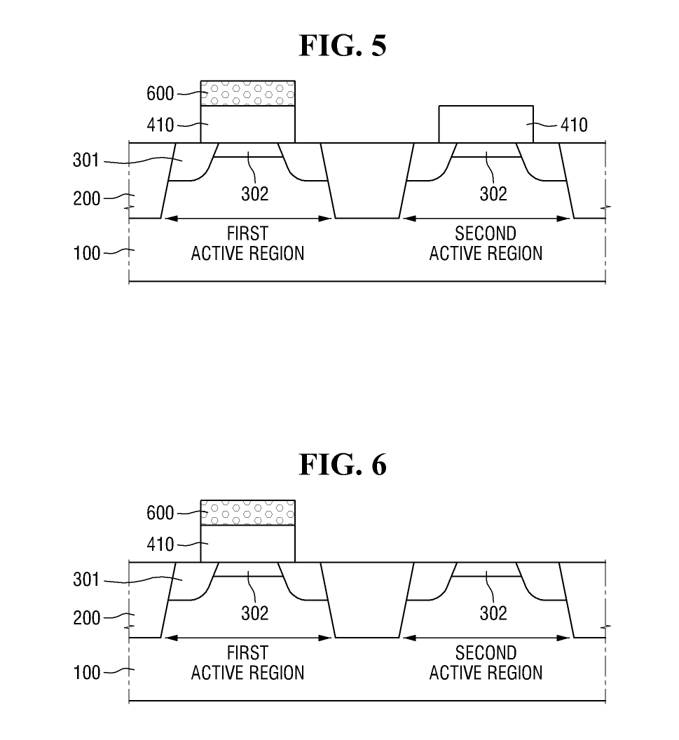

FIGS. 2 to 8 are diagrams illustrating exemplary intermediate processes of a method for fabricating a semiconductor device according to certain embodiments.

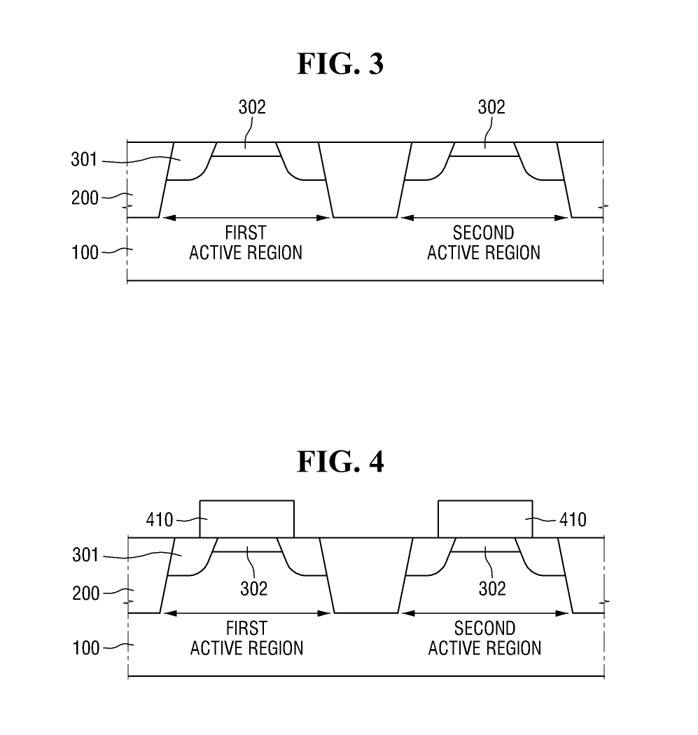

Referring to FIG. 2, first, a substrate 100 in which a first active region and a second active region are defined by a device isolation region 200 is prepared. Next, referring to FIG. 3, a channel region 302 is formed in the first active region and the second active region, respectively, and source/drain regions 301 are formed in the first active region and second active region as well.

Next, referring to FIGS. 4 to 7, a first gate insulating layer 410 and a second gate insulating layer 420 are formed on the first active region and the second gate insulating layer 420 is formed on the second active region. To this end, the first gate insulating layer 410 is formed on the first active region and the second active region and the first gate insulating layer 410 which is formed on the second active region is removed using a mask 600 which covers only the first gate insulating layer 410. Although FIG. 4 shows the first gate insulating layer 410 only disposed on the active regions, this is done in particular for illustrative purposes. In certain embodiments, a first gate insulating layer material may first be deposited on a first section of a semiconductor device that includes a plurality of the first active regions and a second section of the semiconductor device that includes a plurality of the second active regions. The mask may cover the first section including the plurality of first active regions, and the first gate insulating layer 410 may be removed from the second section including the plurality of second active regions.

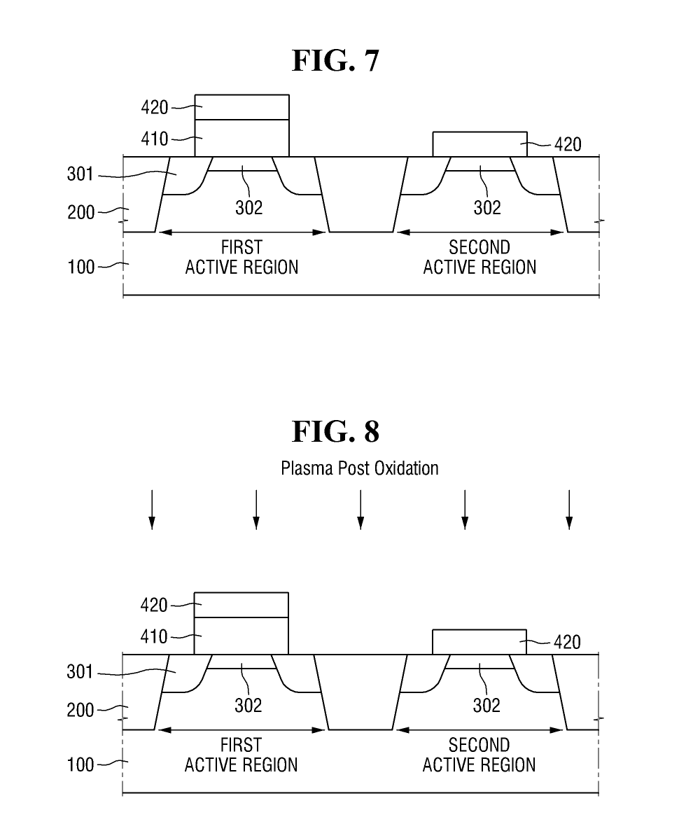

Next, the mask 600 is removed and the second gate insulating layer 420 is formed on the first active region and the second active region. Although FIG. 4 shows the second insulating layer 420 only disposed on the active regions, this is done in particular for illustrative purposes. In certain embodiments, a second gate insulating layer material may be deposited on a first section of a semiconductor device that includes the first gate insulating layer material and the plurality of the first active regions and may be simultaneously formed on the second section of the semiconductor device that includes the plurality of the second active regions. In one embodiment, after the plurality of first active regions are covered with a first and second gate insulating layer material and the plurality of second active regions are covered with the second gate insulating layer material, the particular gate insulating layer patterns shown in FIG. 7 are formed (e.g., by using another mask pattern).

A thickness of the first gate insulating layer 410 may be different from a thickness of the second gate insulating layer 420. Further a thickness of the gate insulating layer which is formed on the first active region may be different from a thickness of the gate insulating layer which is formed on the second active region. The first gate insulating layer 410 and the second gate insulting layer 420 are formed as a double layer on the first active region so that the gate insulating layer on the first active region may be thicker than the gate insulating layer which is formed on the second active region. As described above, the first gate insulating layer 410 and the second gate insulting layer 420 are formed on the first active region and the second gate insulating layer 420 is formed on the second active region using the mask 600 so that gate insulating layers having different thicknesses may be formed on the semiconductor device. Thus, the entire gate insulating layer formed on the first active region may have a greater thickness than the entire gate insulating layer formed on the second active region.

The first gate insulating layer 410 and the second gate insulating layer 420 may include a material having a high dielectric constant (high-K). Specifically, the first gate insulating layer 410 and the second gate insulating layer 420 may include one or more of materials selected from a group consisting of, for example, Al₂O₃, ZnO, HfSiON, HfO, ZrO₂, Ta₂O₅, TiO₂, SrTiO₃, BaTiO₃, and SrTiO₃.

Next, referring to FIG. 8, an interface layer 500 (see, e.g., FIG. 1) is formed between the substrate 100 and the first gate insulating layer 410 which is formed on the first active region and between the substrate 100 and the second gate insulating layer 420 which is formed on the second active region. In one embodiment, the interface layer 500 may be formed using a plasma post oxidation (PPO) process. The PPO process performs an oxidation process in a plasma generated using electron cyclotron resonance (ECR), and when the PPO process is used, an oxidation layer is formed between the substrate 100 and a gate insulating layer. Such an oxidation layer serves as the interface layer 500. For example, when a material which is included in a channel region 302 is germanium (Ge), if the PPO process is used, a GeOx oxidation layer is formed as the interface layer 500. As described above, the interface layer 500 may be simultaneously formed on the first active region and the second active region using the PPO process. In one embodiment as shown in FIGS. 7 and 8, the PPO process is performed on a gate insulating layer 1 and a gate insulating layer 2, each of which has top surfaces and side surfaces exposed.

Though not shown, gate structures and other elements may then be formed on the first active region and second active region. For example, in one embodiment, a structure formed in the first active region is a transistor that may be, for example, a high voltage transistor used for core logic functions, and a structure formed in the second active region is a transistor that may be, for example, a low voltage transistor used for I/O functions. The first transistor may be one of a plurality of transistors formed in first active regions on a semiconductor device, such as a semiconductor chip, formed by the process described above. The second transistor may be one of a plurality of transistors formed in second active regions on a semiconductor device, such as a semiconductor chip, formed by the process described above. As such, a semiconductor chip may include both the first transistor and the second transistor formed in the manner described above. The semiconductor chip may be, for example, a memory chip, a logic chip, or a combination thereof, each of which may include I/O functionality and core logic functionality.

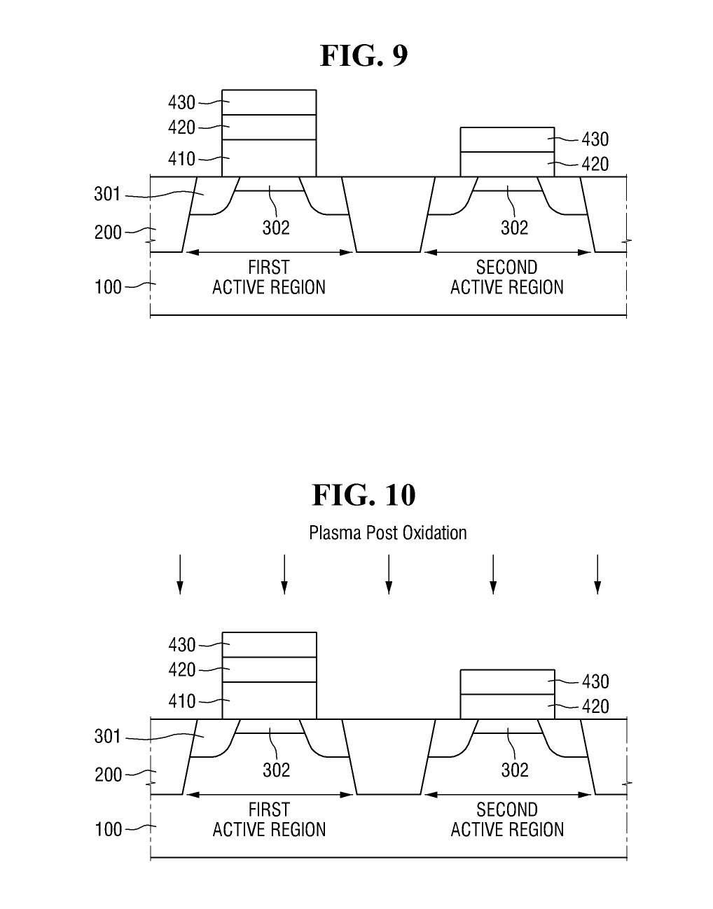

FIGS. 9 to 11 are diagrams illustrating intermediate processes of an exemplary method for fabricating a semiconductor device according to another embodiment. Substantially the same parts and steps as the previously-described method for fabricating a semiconductor device according to the previous embodiment will not be described for the convenience of description.

Referring to FIGS. 2 to 7 and 9, like the method for fabricating a semiconductor device according to the previously-described embodiment, a first gate insulating layer 410 and a second gate insulating layer 420 are formed on a first active region and the second gate insulating layer 420 is formed on a second active region.

The first gate insulating layer 410 is formed on the first active region and the second active region and the first gate insulating layer 410 which is formed on the second active region is removed using a mask 600 which covers only the first gate insulating layer 410. Next, the mask 600 is removed and the second gate insulating layer 420 is formed on the first active region and the second active region. A thickness of the first gate insulating layer 410 may be different from a thickness of the second gate insulating layer 420.

Next, a third gate insulating layer 430 may be further formed on the second gate insulating layer 420 which is formed on the first active region and the second active region. The first gate insulating layer 410, the second gate insulating layer 420, and the third gate insulating layer 430 are formed as a triple layer on the first active region and the second gate insulating layer 420 and the third gate insulating layer 430 are formed as a double layer on the second active region so that the gate insulating layer on the first active region may be thicker than the gate insulating layer which is formed on the second active region. As described above, the first gate insulating layer 410, the second gate insulating layer 420, and the third gate insulating layer 430 are formed on the first active region and the second gate insulating layer 420 and the third gate insulating layer 430 are formed on the second active region using the mask 600 so that gate insulating layers having different thicknesses may be entirely formed on the semiconductor device.

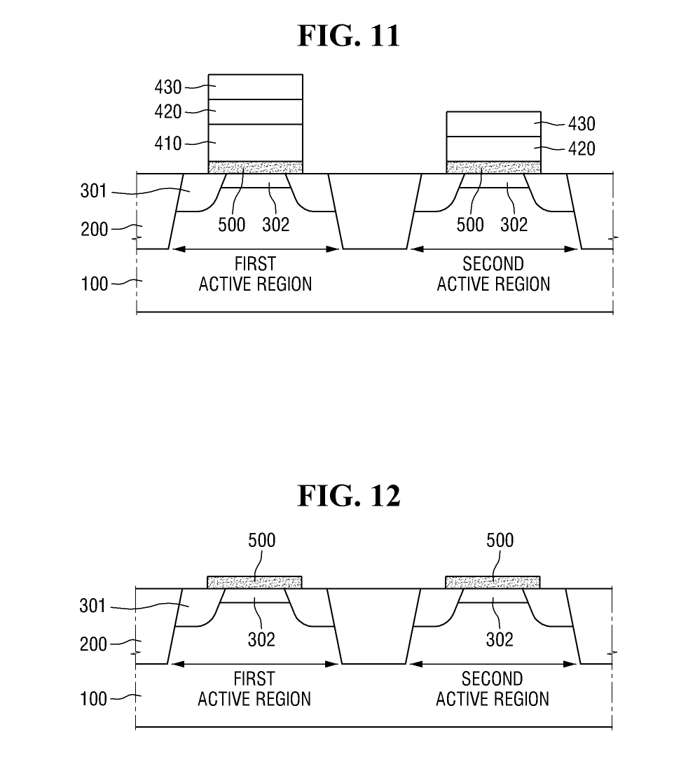

Next, referring to FIGS. 10 and 11, an interface layer 500 is formed between the substrate 100 and the first gate insulating layer 410 which is formed on the first active region and between the substrate 100 and the second gate insulating layer 420 which is formed on the second active region. In this case, the interface layer 500 may be formed using a plasma post oxidation (PPO) process. When the PPO process is used, an oxidation layer is formed between the substrate 100 and the first gate insulating layer 410 and between the substrate 100 and the second gate insulating layer 420. Such an oxidation layer serves as the interface layer 500. For example, when a material which is included in a channel region 302 is germanium (Ge), if the PPO process is used, a GeOx oxidation layer is formed as the interface layer 500. As described above, the interface layer 500 may be simultaneously formed on the first active region and the second active region using the PPO process.

FIGS. 12 to 17 are diagrams illustrating exemplary intermediate processes of a method for fabricating a semiconductor device according to yet another embodiment. Substantially the same parts as the method for fabricating a semiconductor device according to the previously-described embodiment will not be described for the convenience of description.

Referring to FIG. 12, first, an interface layer 500 is formed on a first active region and a second active region. In one embodiment, the interface layer 500 may be formed using an oxidation process.

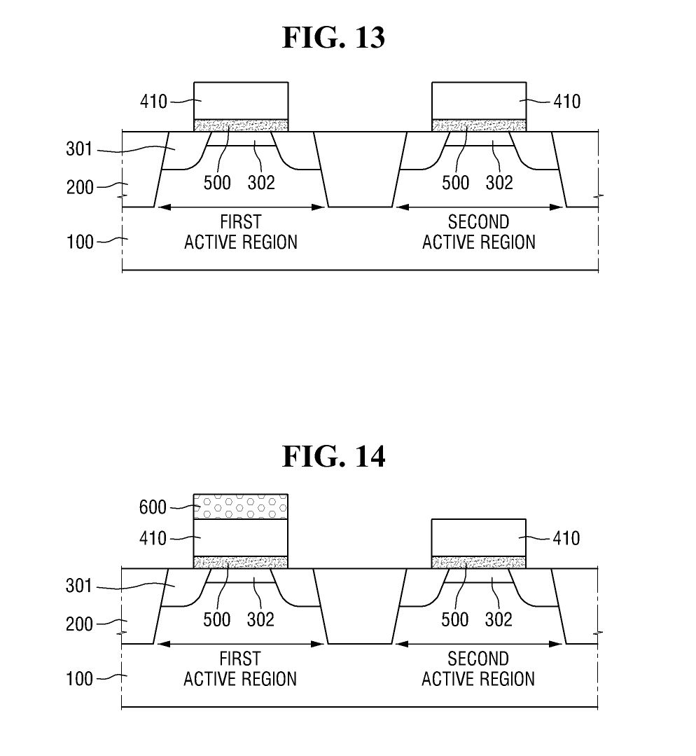

Next, referring to FIG. 13, a first gate insulating layer 410 is formed on the interface layer 500. The first gate insulating layer 410 may be simultaneously formed on the first active region and the second active region.

Next, referring to FIG. 14, a mask 600 covers the first gate insulating layer 410 which is formed on the first active region.

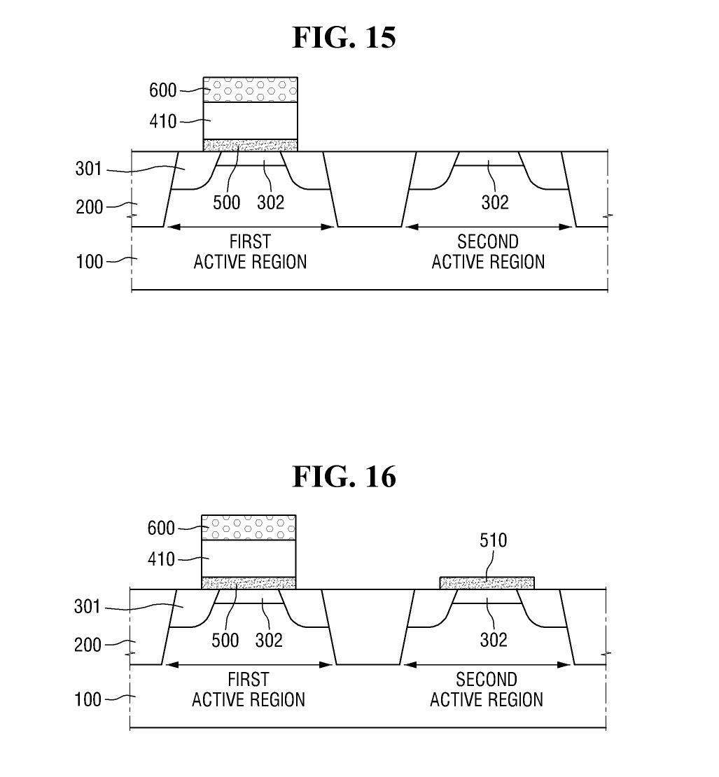

Next, referring to FIG. 15, the first gate insulating layer 410 and the interface layer 500 which are formed on the second active region are removed.

Next, referring to FIG. 16, another interface layer 510 is formed on the second active region. The interface layer 510 may be formed of the same material or have the same thickness as the interface layer 500 which is previously formed. Further, the interface layer 510 may be formed using the same process as the interface layer 500.

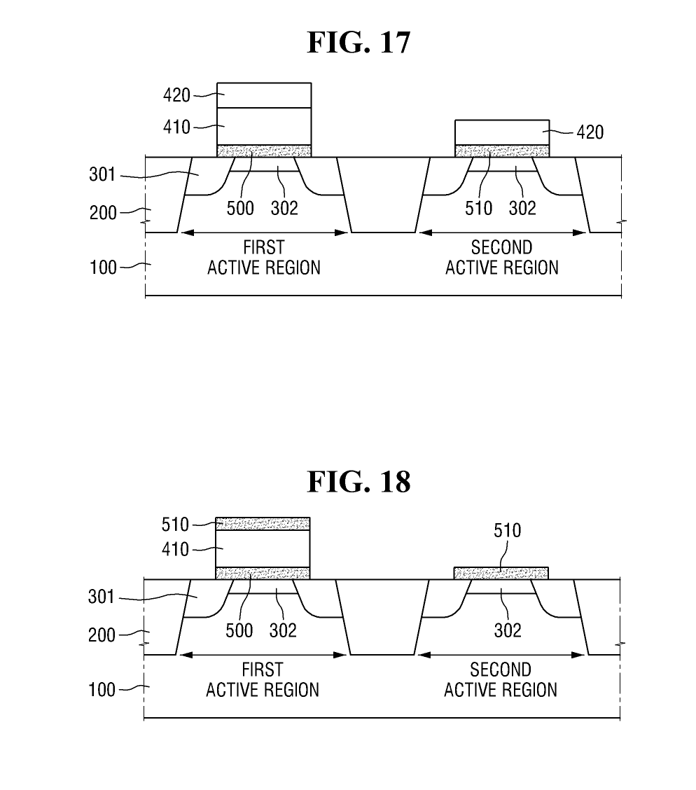

Next, referring to FIG. 17, the mask 600 is removed and a second gate insulating layer 420 is formed on the first gate insulating layer 410 which is formed on the first active region and the second gate insulating layer 420 is formed on the interface layer 510 which is formed on the second active region.

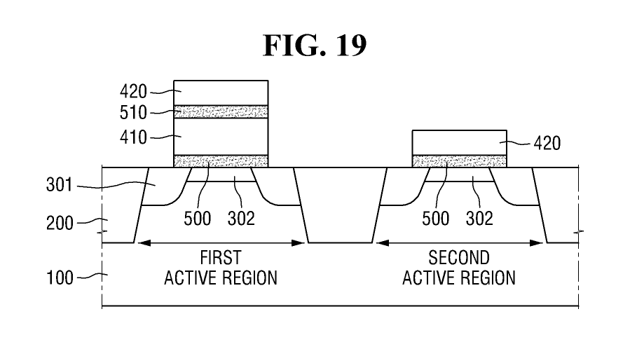

FIGS. 18 and 19 are diagrams illustrating exemplary intermediate processes of a method for fabricating a semiconductor device according to still another embodiment. Substantially the same parts as the method for fabricating a semiconductor device according to the previously-described embodiment will not be described for the convenience of description.

Referring to FIGS. 12 to 15, 18, and 19, first, an interface layer 500 is formed on a first active region and a second active region. In this case, the interface layer 500 may be formed using an oxidation process. Next, a first gate insulating layer 410 is formed on the interface layer 500. The first gate insulating layer 410 may be simultaneously formed on the first active region and the second active region. Next, a mask 600 covers the first gate insulating layer 410 which is formed on the first active region. Next, the first gate insulating layer 410 and the interface layer 500 which are formed on the second active region are removed. Next, the mask 600 is removed and another interface layer 510 is formed on the first active region and the second active region. The interface layer 510 may be formed of the same material or have the same thickness as the interface layer 500 which is previously formed. Further, the interface layer 510 may be formed using the same process as the interface layer 500. Next, a second gate insulating layer 420 is formed on the first active region and the second active region. In this case, all of the second gate insulating layer 420, the interface layer 510, and the first gate insulating layer 410 which are formed on the first active region are insulating materials and may serve as gate insulating layers. As such, a structure in which gate insulating layers are formed on the interface layer 500 is provided. The interface layer 510 is also formed on the second active region and a structure in which the gate insulating layer is formed on the interface layer 510 is provided. However, a thickness of the gate insulating layer which is formed on the first active region is different from a thickness of the gate insulating layer which is formed on the second active region.

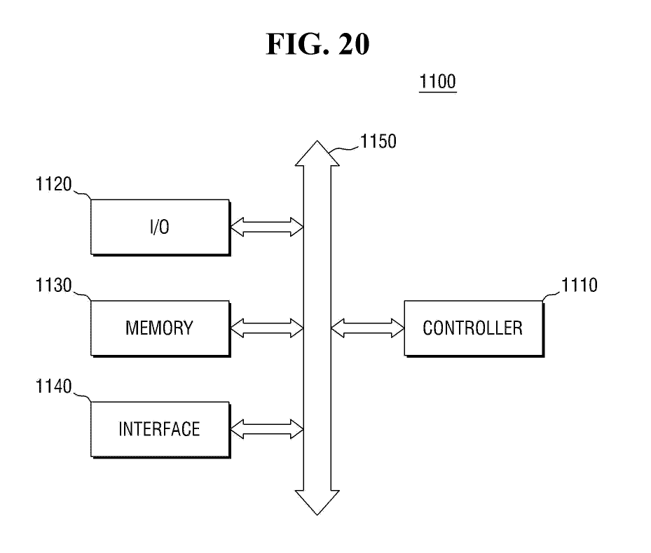

Next, an electronic system which may adopt the semiconductor device according to the embodiments described herein will be described with reference to FIG. 20.

FIG. 20 is a block diagram illustrating an electronic system which includes a semiconductor device according to some embodiments.

Referring to FIG. 20, an exemplary electronic system 1100 according to one embodiment includes a controller 1110, an input/output device (I/O) 1120, a memory device 1130, an interface 1140, and a bus 1150. The controller 1110, the input/output device 1120, the memory device 1130, and/or the interface 1140 may be coupled to each other through the bus 1150. The bus 1150 corresponds to a path through which data moves.

The controller 1110 may include at least one of a microprocessor, a digital signal processor, a micro controller, and logical elements, which may perform a similar function to the above-mentioned devices. The input/output device 1120 may include a keypad, a keyboard, and a display device. The memory device 1130 may store data and/or a command language. As an example, the controller 1110 and/or memory device 1130 may include one or more chips that include the transistors such as described in connection with FIGS. 1-19. The interface 1140 may function to transmit data to a communication network or receive data from the communication network. The interface 1140 may be a wired or wireless type. For example, the interface 1140 may include an antenna or a wired or wireless transceiver. Even though not illustrated, the electronic system 1100 may further include a high speed DRAM and/or SRAM as an operation memory which improves an operation of the controller 1110.

The electronic system 1100 may be applied to a personal digital assistant (PDA), a portable computer, a web tablet, a wireless phone, a mobile phone, a digital music player, a memory card, or all kinds of electronic products which may transmit and/or receive information under a wireless environment.

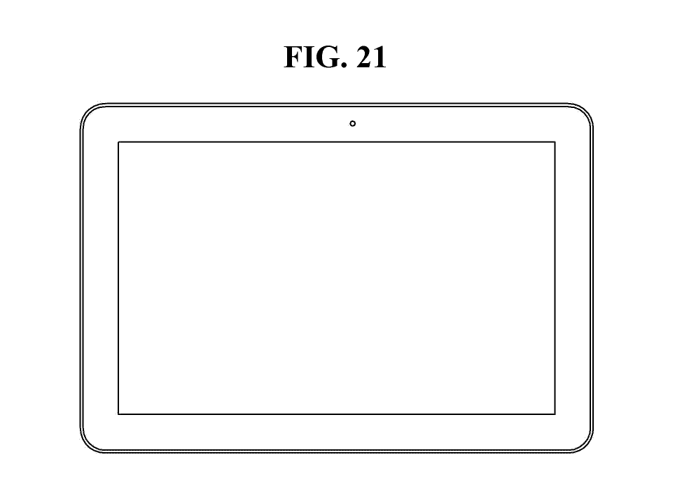

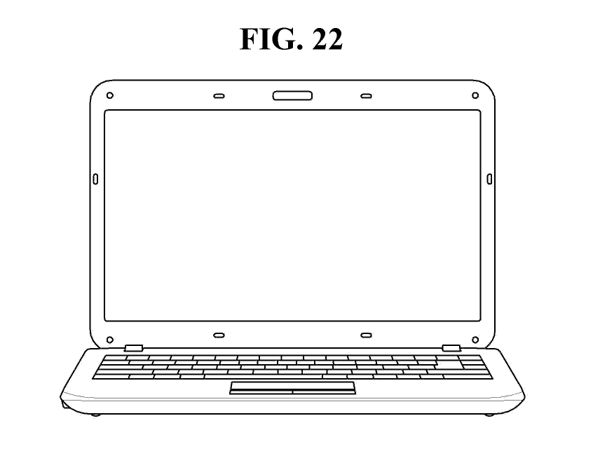

FIGS. 21 and 22 illustrate exemplary semiconductor systems to which a semiconductor device according to some embodiments of the present disclosure is applied. FIG. 21 illustrates a tablet PC and FIG. 22 illustrates a notebook computer. At least one of the semiconductor devices according to the embodiments of the present disclosure may be used for the tablet PC or the notebook computer. In addition, the semiconductor devices according to some embodiments are applied to other integrated circuit devices that have not been exemplified.

Although a few embodiments of the present inventive concept have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of the present inventive concept and is not to be construed as limited to the specific embodiments disclosed, and that modifications to the disclosed embodiments, as well as other embodiments, are intended to be included within the scope of the appended claims. The present inventive concept is defined by the following claims, with equivalents of the claims to be included therein.

What is claimed is:

1. A method of fabricating a semiconductor device, the method comprising:
preparing a substrate in which a first active region and a second active region are defined by a device isolation region;
forming a channel region in the first active region and the second active region, respectively;
forming a first gate insulating layer on the substrate at the first active region;
forming a second gate insulating layer on the first gate insulating layer at the first active region and on the substrate at the second active region,
wherein the first gate insulating layer is disposed between the substrate and the second gate insulating layer at the first active region, and is not disposed between the substrate and the second gate insulating layer at the second active region; and
after forming the first gate insulating layer and second gate insulating layer, forming a first interface layer at an interface between the substrate and the first gate insulating layer at the first active region, and forming a second interface layer at the interface between the substrate and the second gate insulating layer at the second active region.

2. The method of claim 1, further comprising:
forming the first interface layer and second interface layer by performing a plasma post oxidation (PPO) process.

3. The method of claim 1, wherein:
the first gate insulating layer, second gate insulating layer, and first interface layer together form a third gate insulating layer on the substrate at the first active region;
the second gate insulating layer and second interface layer together form a fourth gate insulating layer on the substrate at the second active region; and
a thickness of the third gate insulating layer is between about 2 to 5 times the thickness of the fourth gate insulating layer.

4. The method of claim 1, wherein:
the first interface layer and the second interface layer are formed at the same time.

5. The method of claim 4, wherein:
the second gate insulating layer is formed at the first active region and at the second active region at the same time.

6. The method of claim 5, further comprising:
forming the first gate insulating layer at the second active region at the same time as forming the first gate insulating layer at the first active region; and
removing the first gate insulating layer from the second active region prior to forming the second insulating layer.

7. The method of claim 1, wherein the channel region includes Ge or a III-V group compound.

8. The method of claim 1, wherein the first and second gate insulating layers include Al₂O₃ or HfO.

9. The method of claim 1, wherein:
the structure formed at the first channel region forms part of a high voltage core logic device; and
the structure formed at the second channel region forms part of a low voltage input/output (I/O) device.

10. The method of claim 1, wherein:
the first gate insulating layer and the second gate insulating layer each form a high-K material layer; and
the first interface layer and second interface layer each form a low-K material layer.

11. A method for fabricating a semiconductor device, the method comprising:
preparing a substrate in which a first active region and a second active region are defined by a device isolation region;
forming a channel region in the first active region and the second active region, respectively;
forming a gate insulating layer (referred to as gate insulating layer 1), on the first active region and a gate insulating layer (referred to as gate insulating layer 2), on the second active region, a thickness of the gate insulating layer 1 being greater than a thickness of the gate insulating layer 2; and
forming a first interface layer between the substrate and the gate insulating layer 1 and a second interface layer between the substrate and the gate insulating layer 2.

12. The method of claim 11, wherein the channel region includes Ge or a III-V group compound.

13. The method of claim 11, further comprising:
forming the first interface layer and the second interface layer after forming the gate insulating layer 1 and gate insulating layer 2.

14. The method of claim 13, wherein the forming of the gate insulating layers 1 and 2 is performed by forming a first gate insulating layer on the first and second active regions, removing the first gate insulating layer which is formed on the second active region, and subsequently forming a second gate insulating layer on the first and second active regions.

15. The method of claim 11, wherein the forming of first and second interface layers uses a plasma post oxidation (PPO) process.

16. The method of claim 15, wherein the forming of first and second interface layers is performed simultaneously.

17. The method of claim 11, wherein:
the structure formed at the first channel region forms part of a high voltage core logic device; and
the structure formed at the second channel region forms part of a low voltage input/output (I/O) device.

18. A method of fabricating a semiconductor device, the method comprising:
preparing a substrate in which a first active region and a second active region are defined by a device isolation region;
forming a channel region in the first active region and the second active region, respectively;
forming a first gate insulating layer on the substrate at the first active region;
forming a second gate insulating layer on the first gate insulating layer at the first active region and on the substrate at the second active region, such that the first gate insulating layer and second gate insulating layer at the first active region form a gate insulating layer 1 having exposed top and side surfaces, and the second gate insulating layer at the second region forms a gate insulating layer 2 having exposed top and side surfaces; and
after forming the gate insulating layer 1 and the gate insulating layer 2, forming a first interface layer at an interface between the substrate and the gate insulating layer 1 at the first active region, and forming a second interface layer at the interface between the substrate and the gate insulating layer 2 at the second active region.

19. The method of claim 18, further comprising:
forming the first interface layer and second interface layer by performing a plasma post oxidation (PPO) process on the gate insulating layer 1 having the exposed top and side surfaces and on the gate insulating layer 2 having the exposed top and side surfaces.

20. The method of claim 19, further comprising:
forming the first interface layer and second interface layer simultaneously.
